(19) United States
(12) Patent Application Publication
(10) Pub. No.: US 2023/0246416 A1
(43) Pub. Date: Aug. 3, 2023

(54) METHOD AND APPARATUS FOR FABRICATING OPTICAL RESONANCE STRUCTURE WITH HIGH Q-FACTOR USING ULTRA-THIN 1D GRATING STRUCTURE

(71) Applicant: ELECTRONICS AND TELECOMMUNICATIONS RESEARCH INSTITUTE, Daejeon (KR)

(72) Inventor: Gyeong Cheol PARK, Daejeon (KR)

(21) Appl. No.: 17/890,332

(22) Filed: Aug. 18, 2022

(30) Foreign Application Priority Data
Jan. 28, 2022 (KR) 10-2022-0012959

(51) Int. Cl. H01S 5/14; H01S 5/22

(52) U.S. Cl. CPC H01S 5/141; H01S 5/222

(57) ABSTRACT

An optical resonance structure is provided. For example, an optical resonator may operate based on a single-material double-layer HCG resonance structure. The optical resonator includes a first member and a second member. Each of the first member and the second member has a high contrast grating (HCG) structure, and a refractive index of the first member and a refractive index of the second member are the same.

### CROSS REFERENCE TO RELATED APPLICATION

The present application claims priority to Korean Patent Application No. KR 10-2022-0012959, filed Jan. 28, 2022, the entire content of which is incorporated herein for all purposes by this reference.

### BACKGROUND OF THE INVENTION

### 1. Field of the Invention

The present disclosure relates to an optical resonance method, and more particularly, to an optical resonator used in an optical device and a optoelectronic device.

### 2. Description of Related Art

A broadband high-reflection mirror, a narrowband filter or an optical resonance structure using a single-layer one-dimensional (1D) or two-dimensional (2D) periodic grating structure is used various fields such as optical devices or optoelectronic devices. The 1D periodic structure may be a diffraction grating structure. Specifically, the 1D periodic structure is a structure in which grating composed of a material having a high refractive index and grating composed of an air layer or a material having a low refractive index are repeated. In the 2D periodic structure, a high-refractive-index or low-refractive-index material having a circular, rectangular or elliptical shape is present in one period and a material having a refractive index opposite to the inside of the period is present in the other region.

The role of the single-layer 1D or 2D periodic structure may be determined based on design parameters. For example, the role of the single-layer 1D or 2D periodic structure may be determined according to a period A, a thickness t and the area of a region filled with a high-refractive-index material. An optical resonator is a device capable of storing light of a corresponding resonance wavelength in a resonance structure for a long time. The optical resonator is widely used in optical devices and optoelectronic devices. For example, the optical resonator is widely used in lasers, filters, sensors, photodetectors, and the like. As an existing optical resonator, a resonator in which a Fabry-Perot (FP) structure is formed using two mirrors is widely used.

### SUMMARY OF THE INVENTION

The present disclosure proposes an optical resonance structure with a high Q-factor.

The present disclosure proposes a 1D diffraction grating structure having a high background reflectivity and a quasi-bound states in the continuum (quasi-BIC) structure.

The present disclosure proposes an optical resonance design method with an adjustable Q-factor.

Other objects and advantages of the present disclosure may be understood by the following description, and will become more clearly understood by the embodiments of the present disclosure. Further, it will be readily apparent that the objects and advantages of the present disclosure may be realized by the means and combinations thereof indicated in the appended claims.

As technical means for achieving the above-described technical tasks, an optical resonator comprises a first member and a second member. Each of the first member and the second member has a high contrast grating (HCG) structure, and a refractive index of the first member and a refractive index of the second member are the same. A width of the first member and a width of the second member may be the same. A distance from the center of the second member to the center of a grating may be 0. An area of the first member and an area of the second member may be different. An area of the first member and an area of the second member may be the same. A distance from the center of the first member to the center of a grating and a distance from the center of the second member to the center of the grating may be different.

As technical means for achieving the above-described technical tasks, an optical resonator comprises a first member and a second member. Each of the first member and the second member has a grating structure, and the second member has a high contrast grating (HCG) structure, and a refractive index of the first member and a refractive index of the second member are different. The refractive index of the second member may be higher than 3. A thickness of the second member may be greater than that of the first member. A distance from the center of the second member to the center of a grating may be 0, and the refractive index of the first member may be lower than that of the second member. A distance from the center of the first member to the center of a grating and a distance from the center of the second member to the center of the grating may be different. A width of the first member may be smaller than that of the second member. The refractive index of the first member may be lower than 2. An area of the first member and an area of the second member may be different. A thickness of the first member may be less than that of the second member. The first member may include SiO₂ or TiO₂. The second member may include silicon, InP, InGaAs and Ge.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A and 1B illustrate an HCG resonance structure and a reflection spectrum in a vertical incidence state;

FIG. 2A illustrates a reflectivity spectrum related to a thick HCG structure. FIG. 2B illustrates a high-Q resonance characteristic spectrum according to thickness;

FIGS. 3A to 3C illustrate a resonance structure for using a bound states in the continuum (BIC) phenomenon and a schematic diagram of a BIC laser excited using an external light source;

FIG. 4 illustrates an example for designing a high-Q structure having a single-material double layer from an existing single-layer HCG high-reflection mirror structure according to the present disclosure;

FIGS. 5A and 5B illustrate a reflection spectrum of an HCG high-reflection mirror and a center wavelength |Ey| field distribution according to the present disclosure;

FIG. 6 illustrates a spectral map illustrating a change in Q-factor when a total thickness is the same and the thickness of an upper layer is changed in a single-material double-layer HCG resonance structure according to the present disclosure;

FIGS. 7A to 7D illustrate an excited mode and reflection spectrum in a resonance wavelength according to a movement distance of lower grating of a single-material double-layer HCG resonance structure having the same thickness and width from a unit grating center according to the present disclosure;

FIGS. 8A to 8D illustrate an excited mode and reflection spectrum in a resonance wavelength according to a distance moved from a unit grating center of a lower grating of a single-material double-layer HCG resonance structure having the same thickness and width according to the present disclosure;

FIGS. 9A to 9C illustrate an example of a single-material double-layer and heterogenous-material double-layer high-Q resonance structure in which symmetry is broken in order to design a high-Q resonance structure from an existing single-layer HCG high-reflection mirror structure according to the present disclosure;

FIGS. 10A to 10D illustrates examples for breaking symmetry of an upper layer and a lower layer having the same area from one unit cell according to the present disclosure;

FIGS. 11A to 11D illustrate examples for breaking symmetry of an upper layer and a lower layer having different areas from one unit cell according to the present disclosure;

FIGS. 12A to 12C are diagrams related to a heterogeneous-material double-layer high-Q resonance structure according to the present disclosure;

FIG. 13 illustrates an example of a Q-factor change according to a change in width of a low-refractive-index layer in a heterogeneous-material double-layer high-Q resonance structure using a relatively low-refractive-index material according to the present disclosure;

FIGS. 14A to 14C illustrate an excited mode and reflection spectrum in a resonance wavelength according to an increase in ow of heterogeneous-material double-layer high-Q resonance structure according to the present disclosure;

FIG. 15 illustrates a method of fabricating and operating a single-material double-layer high-Q resonance structure with a variable Q-factor according to the present disclosure;

FIG. 16 illustrates an operation mode of a single-material double-layer resonance structure with a variable Q-factor according to the present disclosure;

FIG. 17 illustrates an example of a high-Q resonance structure according to the present disclosure; and

FIG. 18 illustrates an example of a configuration of a device according to the present disclosure.

### DESCRIPTION OF THE PREFERRED EMBODIMENTS

Hereinafter, exemplary embodiments of the present disclosure will be described in detail with reference to the accompanying drawings so that those skilled in the art may easily implement the present disclosure. However, the present disclosure may be implemented in various different ways, and is not limited to the embodiments described therein.

In describing exemplary embodiments of the present disclosure, well-known functions or constructions will not be described in detail since they may unnecessarily obscure the understanding of the present disclosure. In addition, parts not related to the description of the present disclosure in the drawings are omitted, and similar reference numerals are attached to similar parts.

In the present disclosure, elements that are distinguished from each other are for clearly describing each feature, and do not necessarily mean that the elements are separated. That is, a plurality of elements may be integrated in one hardware or software unit, or one element may be distributed and formed in a plurality of hardware or software units. Therefore, even if not mentioned otherwise, such integrated or distributed embodiments are included in the scope of the present disclosure.

In the present disclosure, elements described in various embodiments do not necessarily mean essential elements, and some of them may be optional elements. Therefore, an embodiment composed of a subset of elements described in an embodiment is also included in the scope of the present disclosure. In addition, embodiments including other elements in addition to the elements described in the various embodiments are also included in the scope of the present disclosure.

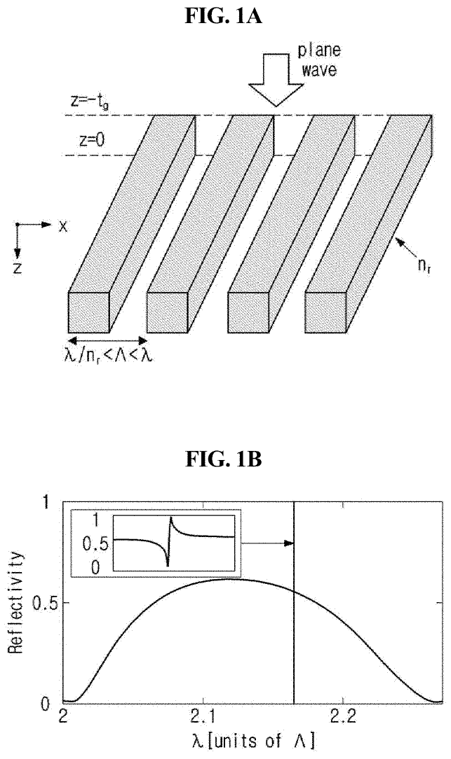

FIGS. 1A and 1B illustrate an HCG resonance structure and a reflection spectrum in a vertical incidence state. Specifically, FIG. 1A illustrates an HCG resonance structure, and FIG. 1B illustrates a reflection spectrum in a vertical incidence state. A resonance phenomenon in which reflectivity rapidly drops to 0 and then rises to 1 between low background reflectivities appears.

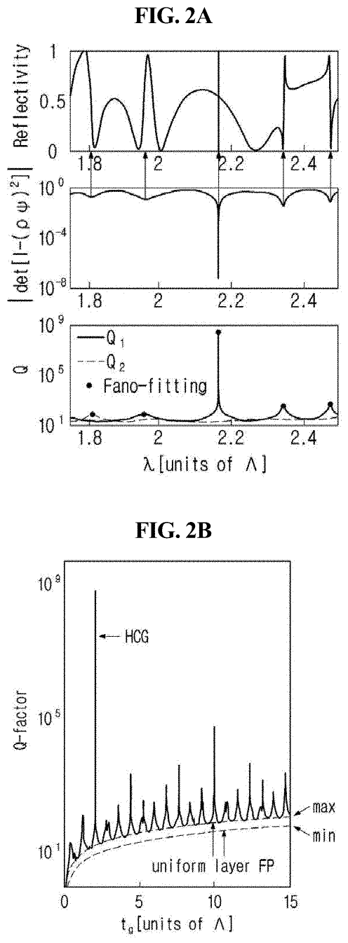

FIG. 2A illustrates a reflectivity spectrum related to a thick HCG structure. FIG. 2B illustrates a high-Q resonance characteristic spectrum according to thickness. Specifically, FIG. 2A illustrates a reflectivity spectrum in a thick HCG structure, a calculation result for a resonance condition and a Q-factor spectrum.

A semiconductor distributed Bragg reflector (DBR) structure is widely used in a short-wavelength vertical-cavity surface-emitting layer (VCSEL). In a long-wavelength VCSEL laser, a Fabry-Perot (FP) resonance structure based on a broadband high-reflection mirror of high contrast grating (HCG) of a 1D grating structure may be formed instead of the DBR structure. Unlike a FP type resonator using two mirrors, a single-layer 1D or 2D periodic grating structure itself may be designed as a resonator. As can be seen in FIGS. 1A, 1B, 2A and 2B, when a resonator is designed by changing design parameters of the single-layer grating structure, the thickness of the grating shall be thicker compared to the HCG mirror. In this case, the broadband high-reflection characteristic of HCG disappears and background reflectivity decreases.

When background reflection decreases around a resonance wavelength, there is a limit in adjustment of decay rates (γ_{dec}) when a photodetector using a resonance structure or an optical refractive index sensor using absorption is designed. Therefore, when background reflection decreases around a resonance wavelength, there may be restrictions on the design of a high-efficiency device.

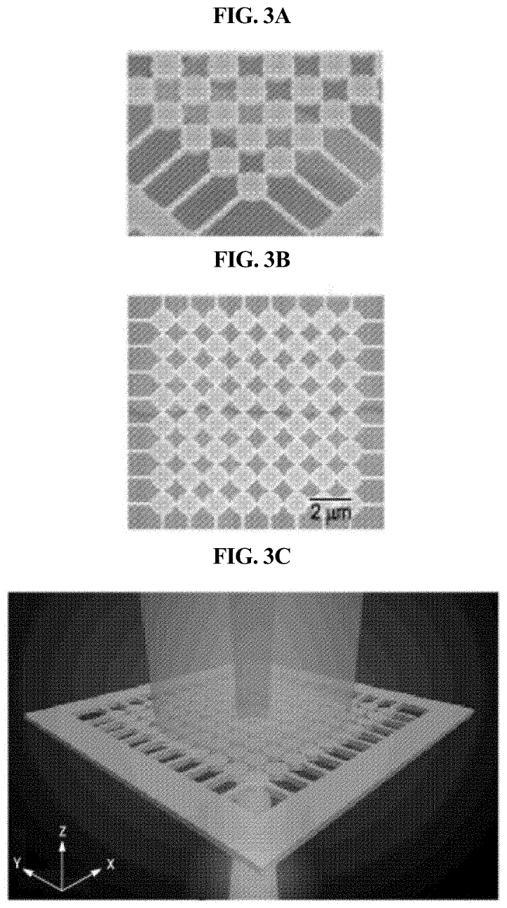

FIGS. 3A to 3C illustrate a resonance structure for using a bound states in the continuum (BIC) phenomenon and a schematic diagram of a BIC laser excited using an external light source. Specifically, FIGS. 3A and 3B illustrate a resonance structure for using an BIC phenomenon and FIG. 3C illustrates a schematic diagram of a BIC laser excited using an external light source.

Recently, as shown in FIGS. 3A to 3C, a resonator with a Q-factor theoretically approachable infinity using a periodic grating structure using an optical BIC phenomenon has been experimentally proven. However, such a resonator has a relatively low background reflection around the resonance wavelength and thus there is a limit on application to various optical devices and optoelectronic devices. A resonance structure with BIC characteristic and high background reflection is suitably applied to various optical devices and optoelectronic devices.

In the case of the HCG-based resonance structure in which the diffraction grating of the HCG structure is thickened, the background reflectivity is low, unlike the HCG mirror. When the background reflection is low, in the two-port resonance structure, adjustment of two decay rates (input terminal: γ_{dec1}, output terminal: γ_{dec2}) at which the optical power stored in the resonator exits through each port, that is, the light incident side and the output side through the resonance structure, may be more restrictive. Accordingly, when an absorbing material is included in the resonance structure, it may be difficult to satisfy a critical coupling condition in which the rate at which the optical power stored in the resonance structure exits and the rate at which the absorbing material is absorbed are the same.

However, when the background reflection is high, it is easy to adjust the ratio of the exiting optical power to the absorbed optical power. For example, when the background reflection is high, the optical power exiting through the output terminal is very small, so that the 2-port resonance structure may operate like a 1-port resonance structure. Accordingly, the ratio of the optical power that exits to the input terminal and the optical power that is absorbed may be adjusted to be equal. Therefore, it is more advantageous to have high background reflectivity for various optical and optoelectronic device applications.

A Q-factor can be changed sensitively according to the HCG thickness condition. If the HCG deviates from the design thickness, the Q-factor can drop significantly. Even a BIC resonator has low background reflection and thus there is a limit in its applications other than lasers. To solve this problem, a 1D diffraction grating structure having a quasi-BIC structure while background reflectivity has high reflectivity of 95% or more is proposed. In addition, it shall be easy to design a resonance structure to obtain a Q-factor as desired. Through this, it is possible to design a resonator with a high Q-factor or a desired degree of Q-factor, and the background reflection around the resonance wavelength is high and thus it can be widely applied not only to lasers but also to photodetectors and absorption type optical refractive index sensors. In addition, the Q-factor may be adjusted passively or actively, so it may be applied to various optical and optoelectronic devices.

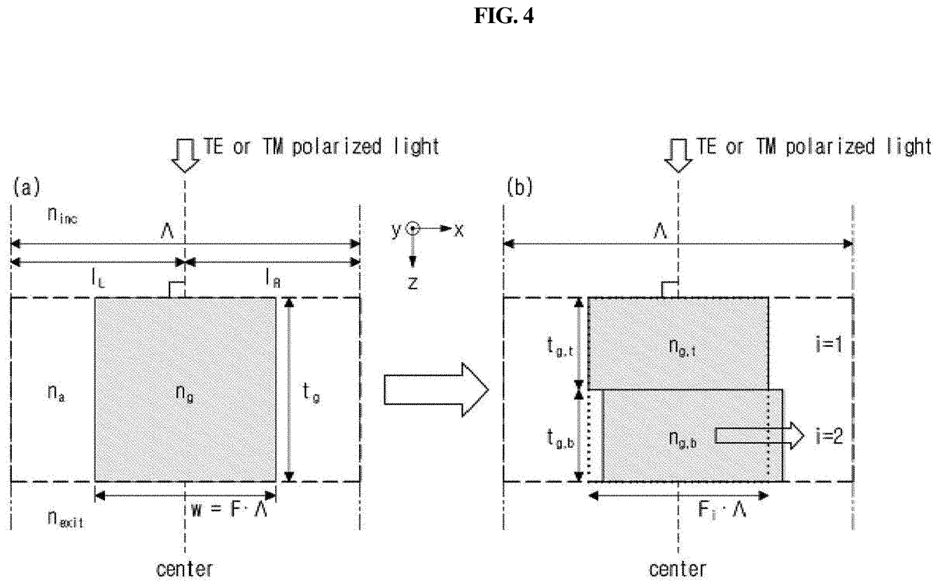

FIG. 4 illustrates an example for designing a high-Q structure having a single-material double layer from an existing single-layer HCG high-reflection mirror structure according to the present disclosure. Referring to FIG. 4, (a) of FIG. 4 illustrates an HCG high-reflection structure mirror. Referring to FIG. 4, (b) of FIG. 4 illustrates a cross-section of an HCG high-Q resonance structure. The double-layer high-Q resonator design starts with a single-layer high contrast grating (HCG) high-reflection mirror. Referring to (a) of FIG. 4, the HCG high-reflection mirror in the unit grating operates as a high-reflection mirror for TE (transverse electric) or TM (transverse magnetic) polarized light incident to the 1D diffraction grating. TE, polarized light corresponds to the case where the electric field component of the incident light coincides with the y-axis direction, which is the direction of the 1D diffraction grating. TM polarized light corresponds to the case where the magnetic field component is in the y-axis direction. The high-reflection mirror designed for TE polarized light does not show high reflection characteristics for TM polarized light. Like the meaning of the name of the HCG mirror, the high refractive index (n_{g}) component of the 1D diffraction grating is greater than the low refractive index (nₐ) by 2 or more. A high-refractive-index material may include a material having a refractive index of 3 or higher. For example, the high-refractive-index material may include a material such as silicon and InP/InGaAs, or a material having a refractive index of 3 or higher, such as Ge. A low-refractive-index material may include a material having a refractive index of 2 or less. For example, the low-refractive-index material may include air, SiO2, or bisbenzocyclobutene (BCB). In (a) of FIG. 4, it is assumed that the high-refractive-index material is InP (n_{g}=3.17) and the low-refractive-index material is air (nₐ=1). It is assumed that the region where light is incident (n_{inc}) to the HCG high-reflection mirror and the region where light is output (nₑₓᵢₜ) from the HCG high-reflection mirror is air. The single-layer high-reflection mirror design of a relatively wide region centered on the center wavelength (λ₀) is possible by adjusting the unit grating period (Λ), thickness (t_{g}), the ratio of high refractive index grating width (w) to the high-refractive-index material.

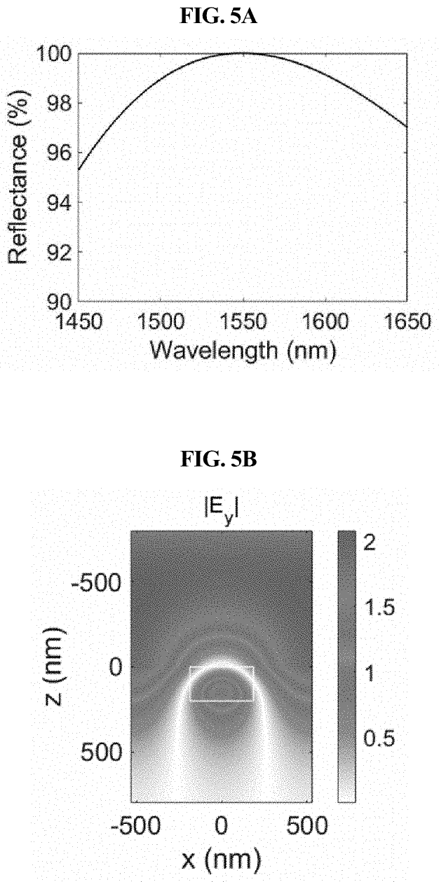

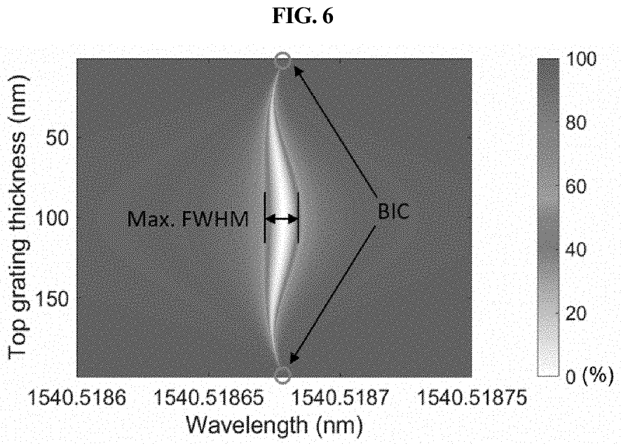

FIGS. 5A and 5B illustrate a reflection spectrum of an HCG high-reflection mirror and a center wavelength |Ey| field distribution according to the present disclosure. FIG. 6 illustrates a spectral map illustrating a change in Q-factor when a total thickness is the same and the thickness of an upper layer is changed in a single-material double-layer HCG resonance structure according to the present disclosure.

FIG. 5A illustrates that the designed HCG high-reflection mirror has reflectance of 98% or more over a 100 nm wavelength band. FIG. 5B illustrates the distribution of the |Ey| field excited at the center wavelength. Most of the light incident around the center wavelength (λ₀=1550 nm) may be reflected. A maximum |Ey| field size is around 2. As shown in (a) of FIG. 4, in the case of the HCG high-reflection mirror, the high refractive index diffraction gap may be located at the center of the unit grating. Accordingly, the distances from the center position of the diffraction grating to the left and right boundaries of the unit grating may be the same. That is, l_{L}=l_{R}.

In order to change the HCG high-reflection mirror to the HCG-based high-Q resonance structure, the single-layer diffraction grating is divided into two layers (i=1, i=2), and then a lower (or upper) layer is moved from the center of the existing diffraction grating to deviate from the center of the existing diffraction grating, breaking symmetry. (b) of FIG. 4 illustrates an example in which single-layer diffraction grating is divided into two layers, and then a lower layer is moved from the center of the existing diffraction grating to deviate from the center of the existing diffraction grating. A sum of the total thicknesses of the two gratings is equal to the thickness of the HCG high-reflection mirror. The layers have a thickness of t_{g,t} and t_{g,b}, respectively. The thicknesses of the two layers need not be the same. Referring to FIG. 6, as the thickness of one layer deviating from the center of the diffraction grating becomes thinner, the Q-factor increases. If the two layers have the same thickness, the full-width half-maximum (FWHM) is the widest and thus the Q-factor is the smallest. When the thickness of one layer converges to 0, it converges to the HCG high-reflection mirror again. Accordingly, when the thickness of one layer converges to zero, the high-Q resonance characteristic cannot be used. This is because the BIC resonance characteristic is shown at the converging wavelength, and thus it is completely trapped in the resonance structure. The diffraction grating layer deviating from the center does not matter if it is top or bottom. That is, only one layer needs to deviate from the center. As shown in (b) of FIG. 4, when the deviation distance of one diffraction grating layer from the center of the single grating increases more and more, the Q-factor gradually decreases. Therefore, it is possible to design a single-material double-layer HCG resonance structure with a higher Q-factor as the distance deviating from the center is shorter.

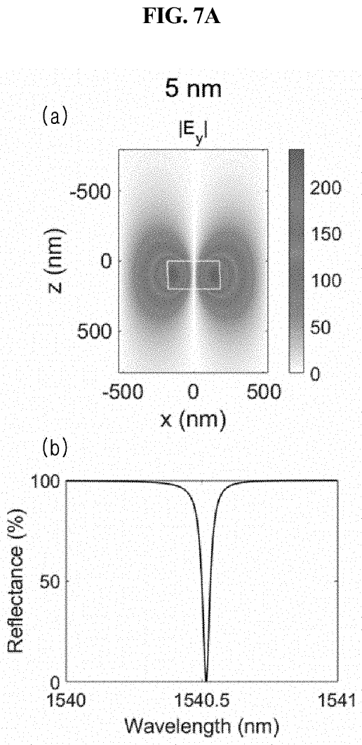

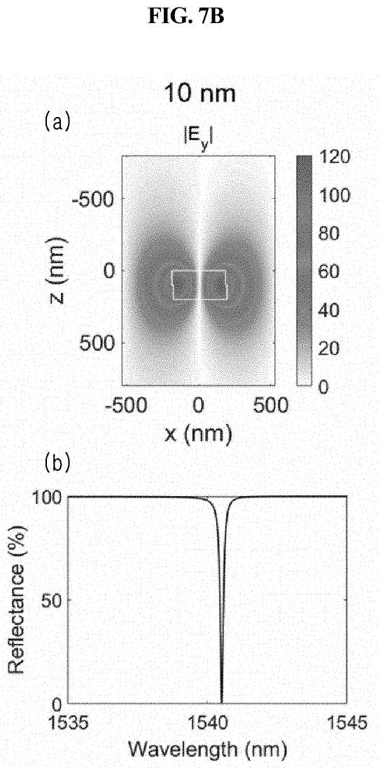

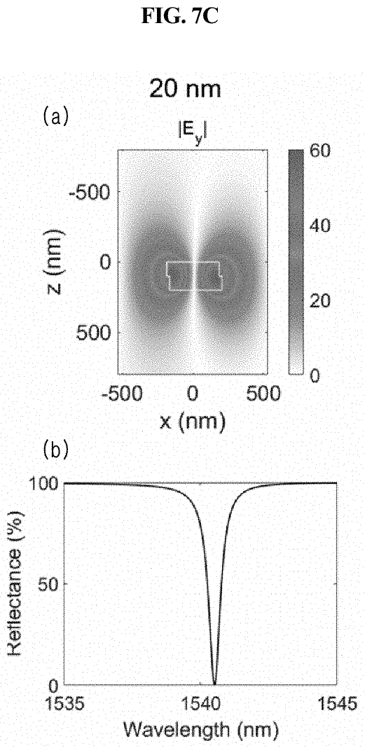

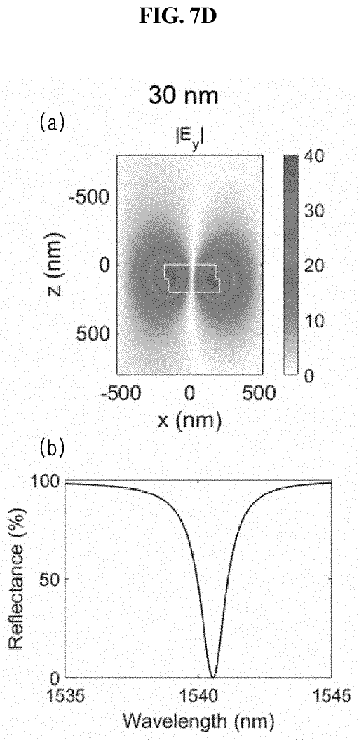

FIGS. 7A to 7D illustrate an excited mode and reflection spectrum in a resonance wavelength according to a movement distance of lower grating of a single-material double-layer HCG resonance structure having the same thickness and width from a unit grating center according to the present disclosure. (a) of each of FIGS. 7A to 7D illustrates the excited mode a at the corresponding resonance wavelength as the lower layer of the single-material double-layer HCG resonance structure having the same upper and lower layer thickness moves to the right by 5 nm/10 nm/20 nm/30 nm, respectively. (b) of each of FIGS. 7A to 7D illustrates the reflection spectrum b as the lower layer of the single-material double-layer HCG resonance structure having the same upper and lower layer thicknesses moves to the right by 5 nm/10 nm/20 nm/30 nm, respectively. From the reflection spectrum, the Q-factor can be calculated. For example, the Q-factor may be calculated according to a λr/Δλ equation.

In the case of FIG. 7A, as the lower layer of the single-material double-layer HCG resonance structure having the same upper and lower layer thickness moves to the right by 5 nm, the Q-factor may be calculated as 47532. In the case of FIG. 7B, as the lower layer of the single-material double-layer HCG resonance structure having the same upper and lower thickness moves to the right by 10 nm, the Q-factor may be calculated as 11859. In the case of FIG. 7C, as the lower layer of the single-material double-layer HCG resonance structure having the same upper and lower thickness shifts to the right by 20 nm, the Q-factor can be calculated as 2971. In the case of FIG. 7D, as the lower layer of the single-material double-layer HCG resonance structure having the same upper and lower thickness moves to the right by 30 nm, the Q-factor may be calculated as 1321.

It can be seen that, when moving by a distance of 5 nm, the Q-factor is 47,532, which is very high, and the maximum value of the excited |Ey| field strength also exceeds 200. As the movement distance increases, the FWHM of the reflection spectrum may be widened. Accordingly, the Q-factor may also be lowered. The excited |Ey| field strength may also be lowered. However, the shape of the excited modes is almost similar.

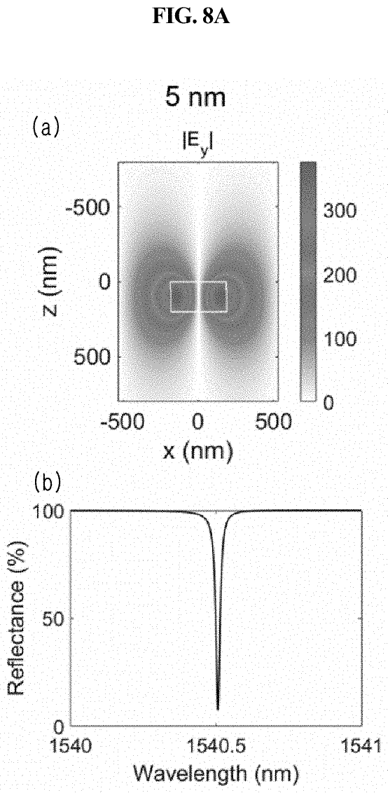

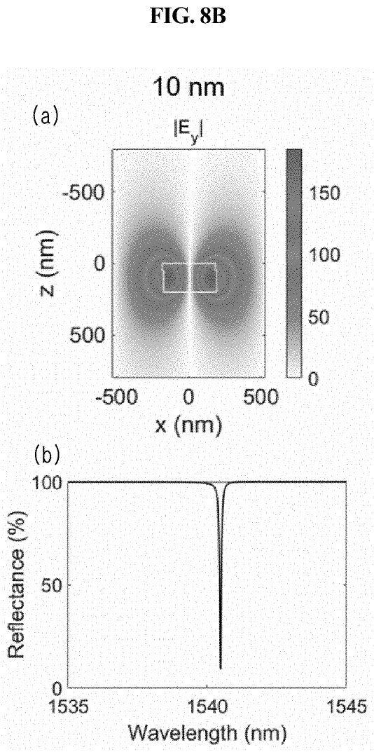

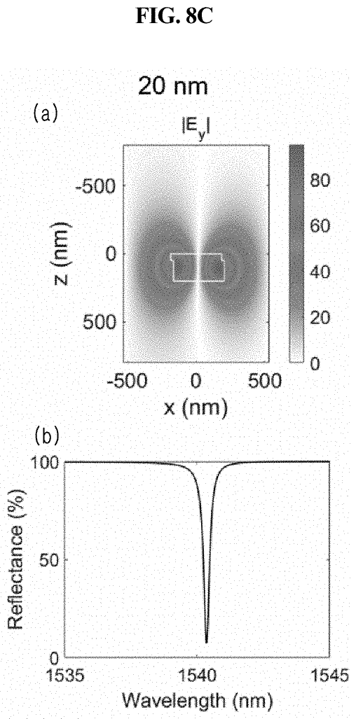

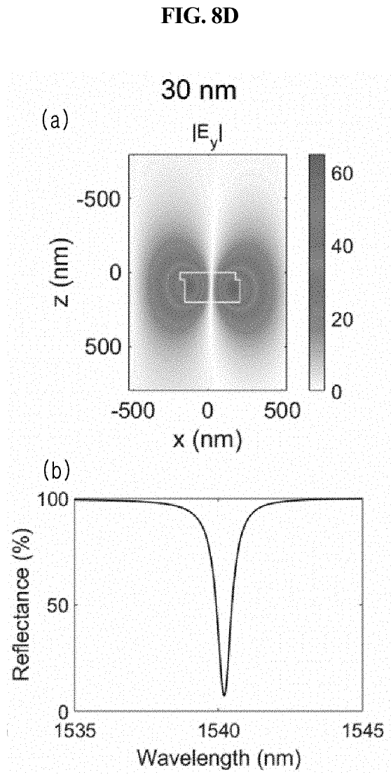

FIGS. 8A to 8D illustrate an excited mode and reflection spectrum in a resonance wavelength according to a distance moved from a unit grating center of a lower grating of a single-material double-layer HCG resonance structure having the same thickness and width according to the present disclosure.

FIGS. 8A to 8D illustrate the excited mode distribution a and reflection spectrum b at the corresponding resonance wavelength as the lower layer of the single-material double-layer HCG resonance structure moves to the right by 5 nm/10 nm/20 nm/30 nm when the upper layer thickness is thinner than the lower layer thickness by ⅓. If the thickness of one layer is thin, it may be closer to the BIC as shown in FIG. 6. Accordingly, it can be seen that the Q-factor increases compared to the case of FIGS. 7A to 7D.

FIG. 8A illustrates the case where the lower grating of the single-material double-layer HCG resonance structure having different thicknesses and the same width moves by 5 nm from the center of the unit grating. In this case, the Q-factor is 100,358. FIG. 8B illustrates the case where the lower grating of the single-material double-layer HCG resonance structure having different thicknesses and the same width moves by 10 nm from the center of the unit grating. In this case, the Q-factor is 24,886. FIG. 8C illustrates the case where the lower grating of the single-material double-layer HCG resonance structure having different thicknesses and the same width moves by 20 nm from the center of the unit grating. In this case, the Q-factor is 6279. FIG. 8D illustrates the case where the lower grating of the single-material double-layer HCG resonance structure having different thicknesses and the same width moves by 30 nm from the center of the unit grating. In this case, the Q-factor is 2795.

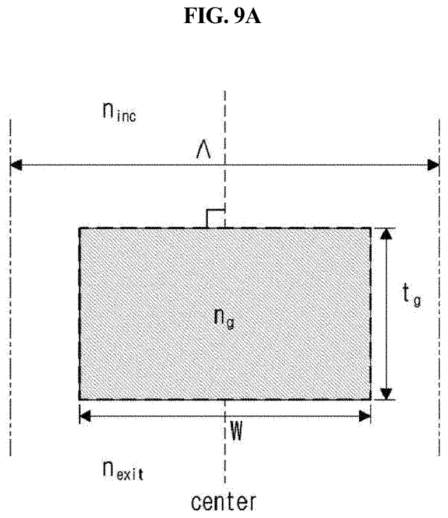

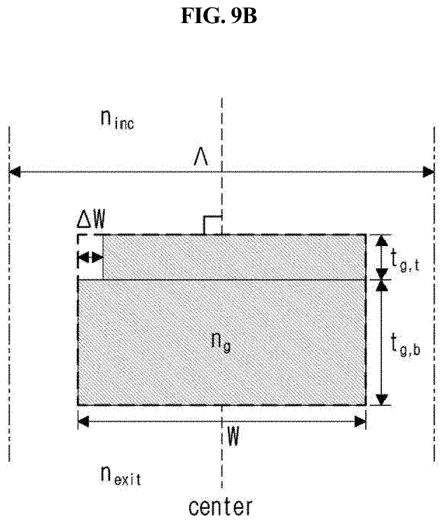

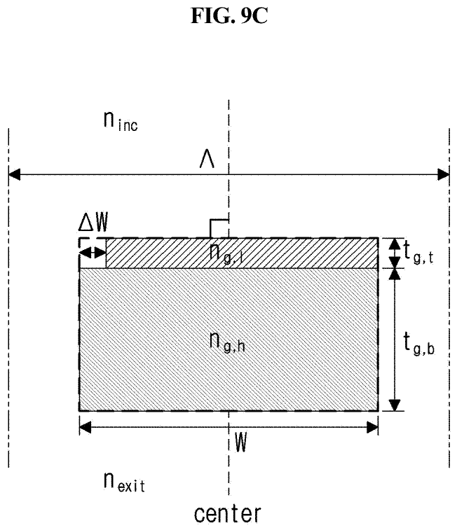

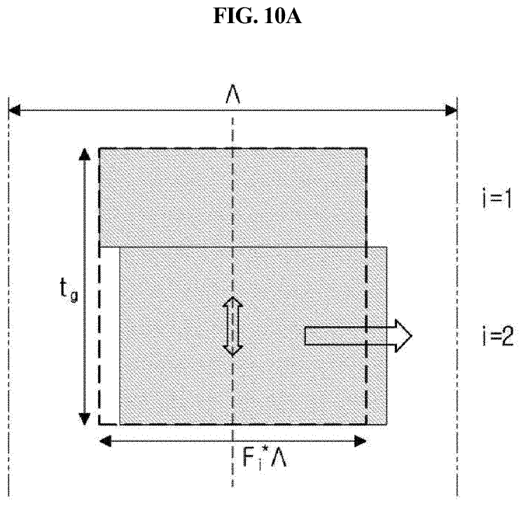

FIGS. 9A to 9C illustrate an example of a single-material double-layer and heterogenous-material double-layer high-Q resonance structure in which symmetry is broken in order to design a high-Q resonance structure from an existing single-layer HCG high-reflection mirror structure according to the present disclosure. FIG. 9A illustrates an example of an HCG high-reflection structure mirror. FIG. 9B illustrates an example of a single-material double-layer high-Q resonance structure. FIG. 9C illustrates an example of a heterogeneous-material double-layer high-Q resonance structure.

FIG. 9A to 9C illustrate an HCG high-reflection mirror, a single-material double-layer high-Q resonance structure, and a heterogeneous-material double-layer high-Q resonance structure. The single-material double-layer high-Q resonance structure of FIG. 9B shows high-Q resonance characteristics when the center of one layer is designed to deviate from the center of the single grating, similar to the related description of (b) of FIG. 4. In the single-material double-layer high-Q resonance structure shown herein, when the width w of the diffraction grating of the upper layer is reduced by Aw, unlike the (b) of FIG. 4. Even in this case, the same effect as if the center of the upper layer deviated from the center of the single grating as a result may be obtained. Therefore, even in this case, the modified mirror may operate with a high-Q resonance structure.

For the thicknesses of the upper and lower layers, the sum of t_{g,t} and t_{g,b} shall be equal to the thickness of the HCG high-reflection mirror illustrated in FIG. 9(a). As described above, the Q-factor may be determined according to the thicknesses of the two layers. In the case of the heterogeneous-material double-layer high-Q resonance structure of FIG. 9C, the refractive index of one layer may be lower. For example, one layer may be composed of a low-refractive-index material such as SiO₂, Al₂O₃, or the like. A layer having a low refractive index may serve to break symmetry. The high-refractive-index diffraction grating layer shall still have the characteristics of HCG high-reflection mirror. Therefore, in order to maintain HCG high reflection characteristics, the low-refractive-index layer may be limited in thickness (t_{g,t}) unlike the single-material double-layer high-Q resonance structure illustrated in FIG. 5B.

Unlike the single-material double-layer high-Q resonance structure, in the heterogeneous-material double-layer resonance structure, in the case where the sum of the thicknesses of the two layers is equally maintained, if the low-refractive-index layer is too thickened, the HCG high-reflection characteristics of the lower layer may disappear. Therefore, the high-Q characteristics that may be obtained by breaking the symmetry in the HCG high-reflection mirror cannot be obtained. However, in the case of a heterogeneous-material double-layer high-Q resonance structure using the low-refractive-index material, the Q-factor is designed to be similar to or greater than that of a single-material double-layer high-Q resonance structure, even when a relatively larger Aw is used to break the symmetry. In addition, in the case of the thickness (t_{g,t}) of the low-refractive-index layer, it is possible to design a high-Q resonance structure even when the thickness is several nm, and deposit capable of accurately controlling the thickness using an ALD (atomic layer deposition) method is possible.

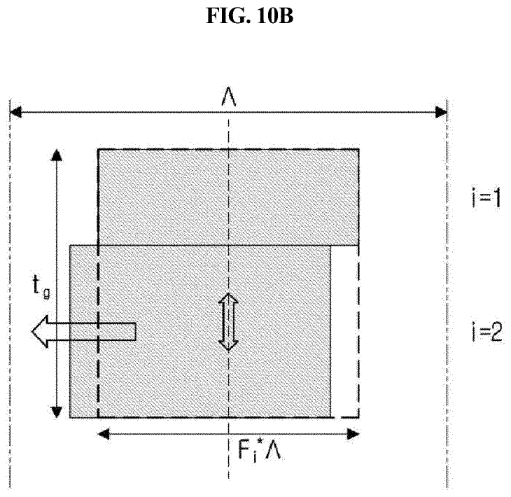

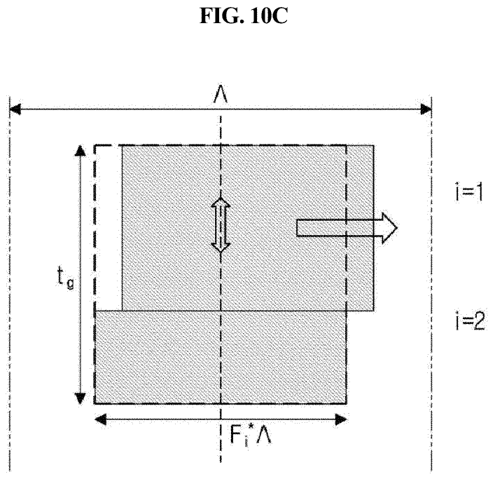

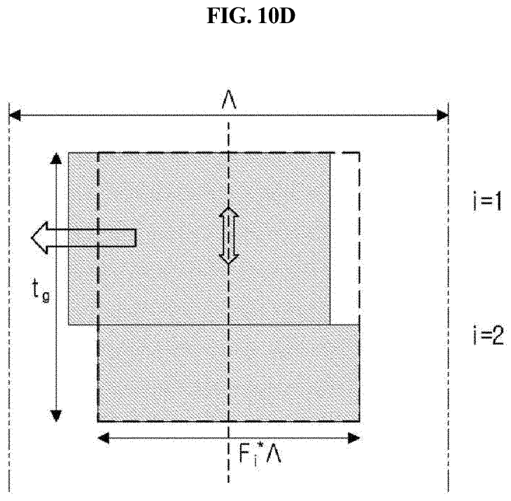

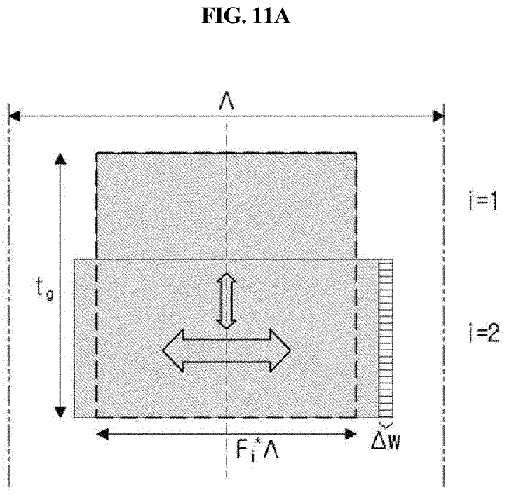

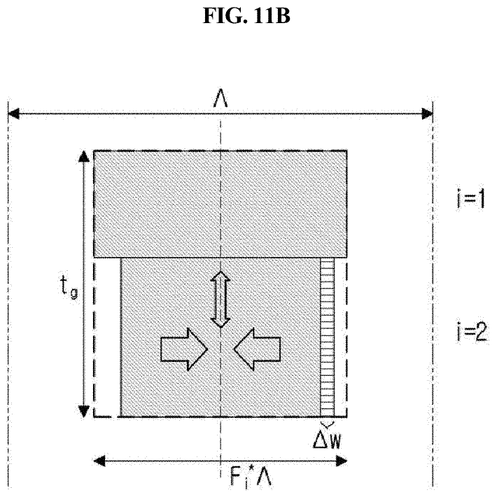

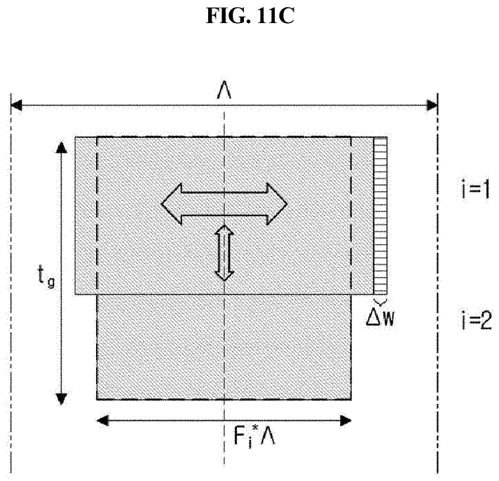

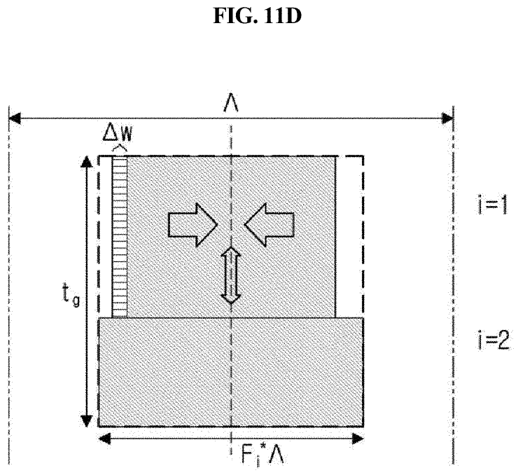

FIGS. 10A to 10D illustrates examples for breaking symmetry of an upper layer and a lower layer having the same area from one unit cell according to the present disclosure. Specifically, FIGS. 10A to 10D illustrate examples for breaking the symmetry of an upper layer and a lower layer having the same area from one unit cell in order to design a single-material double-layer high-Q resonance structure. FIGS. 11A to 11D illustrate examples for breaking symmetry of an upper layer and a lower layer having different areas from one unit cell according to the present disclosure. Specifically, FIGS. 11A to 11D illustrate examples for breaking the symmetry of an upper layer and a lower layer having different areas from one unit cell in order to design a single-material double-layer high-Q resonance structure.

FIGS. 10A to 10D and 11A to 11D illustrate four representative cases of breaking the symmetry for the design of a single-material double-layer high-Q resonance structure, respectively. However, cases of breaking the symmetry may be various and are not limited to this embodiment. In FIGS. 10A to 10D, the two layers of each diffraction grating have the same width, but may have the same or different thickness. However, the thickness of one layer of the mirror shall not be zero. To break the symmetry, the diffraction grating of the lower or upper layer may move from the center of single grating to the left or right.

FIGS. 11A to 11D illustrate a case in which the width of one layer is narrowed or widened, and a case in which the width is additionally increased by Aw in order to break the symmetry of the upper and lower layers. In order to break the symmetry in the single-material double-layer structure, in addition to the four representative examples of each of FIGS. 10A to 10D and 11A to 11D, when the center of one layer is deviated from the center of single grating through a combination thereof, it may operate as a high-Q resonator.

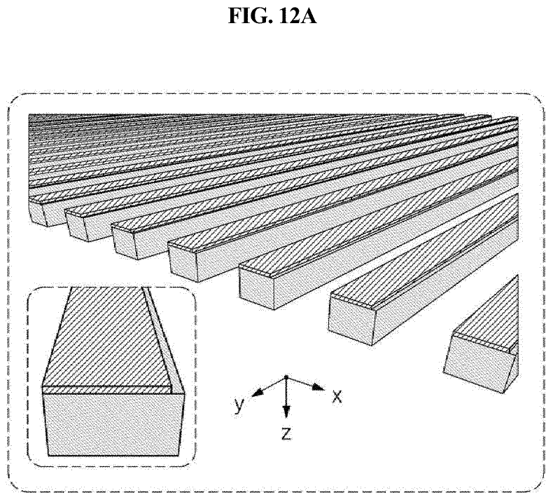

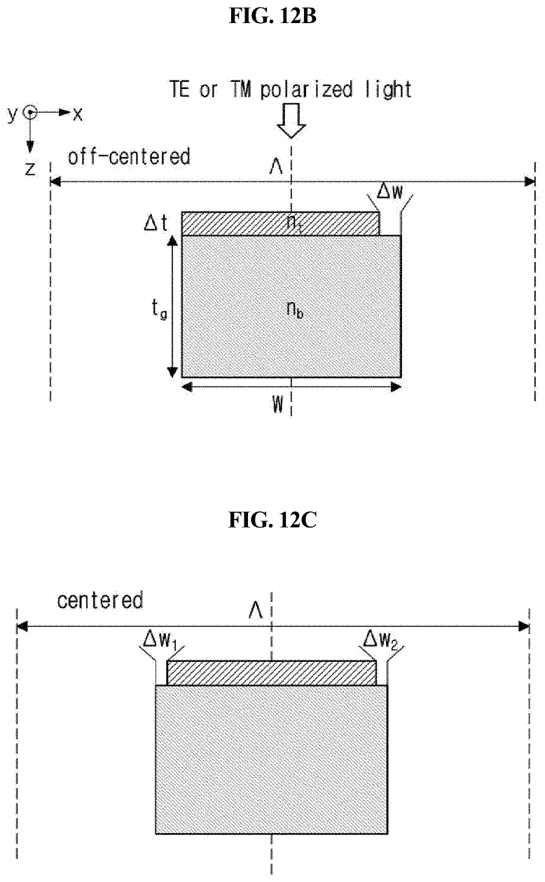

FIGS. 12A to 12C are diagrams related to a heterogeneous-material double-layer high-Q resonance structure according to the present disclosure. Specifically, FIG. 12A illustrates an elevation view of a heterogeneous-material double-layer high-Q resonance structure and an enlarged single grating structure. FIG. 12B is a cross-sectional view in which the symmetry is broken by moving the low-refractive-index layer having a narrow width of the heterogeneous-material double-layer high-Q resonance structure to the left by Aw. FIG. 12C is a cross-sectional view illustrating a case in which the low-refractive-index layer is reduced by Δw1=Δw2 on the left and right so that symmetry is not broken.

FIG. 12A is an elevation view for a heterogeneous-material double-layer high-Q resonance structure and an enlarged view of a single grating structure. The heterogeneous-material double-layer high-Q resonance structure may be designed as a resonator having high-Q characteristics even when the diffraction grating includes materials having optically different refractive indices. However, when a relatively low-refractive-index material is used for the heterogeneous-material double-layer high-Q resonance structure, high-Q characteristics may be obtained even when Δw is wider than that of the single-material double-layer high-Q resonance structure. Therefore, the heterogeneous-material double-layer high-Q resonance structure has advantages in terms of actual experimental implementation. Referring to FIG. 12B, the heterogeneous-material double-layer high-Q resonance structure is a modified form of the HCG high-reflection mirror structure. On the HCG high-reflection mirror structure having a high refractive index n_{b}, a material having a low refractive index nₜ deviates from the center of single grating and its width is reduced by Δw compared to that of the high-refractive-index layer. The low-refractive-index layer has a thickness Δt, which is very thin compared to the high-refractive-index layer of the lower layer. The high-refractive-index layer of the lower layer is thick enough to have the characteristics of an HCG high-reflection mirror. The heterogeneous-material double-layer HCG structure of FIG. 12B may induce high-Q resonance characteristics by breaking the symmetry by the low-refractive-index layer.

FIG. 12C illustrates a heterogeneous-material double-layer high-Q structure. Referring to FIG. 12C, since Δw1=Δw2, the low-refractive-index layer may be located at the center of single grating. In this case, the mirror may operate as an HCG high-reflection mirror rather than a high-Q resonance structure. However, when Δw1≠Δw2, the symmetry is broken. Accordingly, the mirror can operate as a heterogeneous-material double-layer high-Q resonator because the low-refractive-index layer deviates from the center of the single grating.

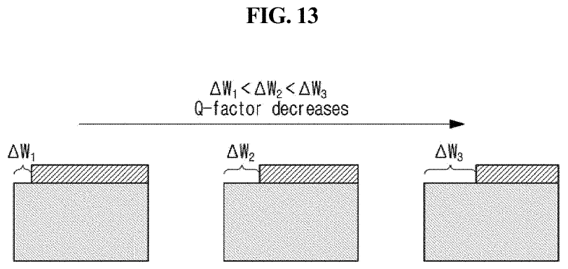

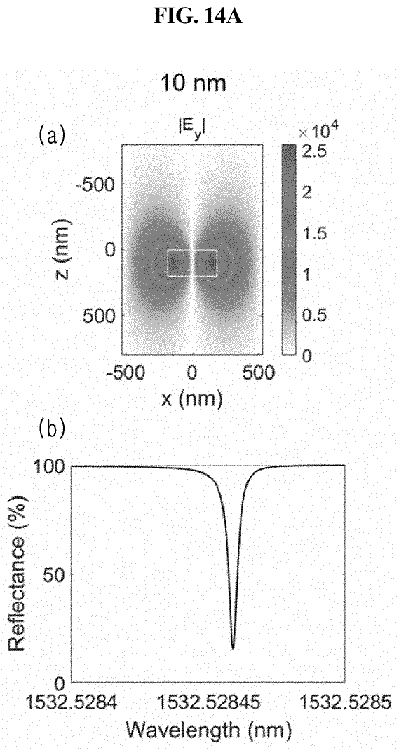

FIG. 13 illustrates an example of a Q-factor change according to a change in width of a low-refractive-index layer in a heterogeneous-material double-layer high-Q resonance structure using a relatively low-refractive-index material according to the present disclosure. Specifically, FIG. 13 schematically illustrates the Q-factor change according to the increase in Δw of a heterogeneous-material double-layer high-Q resonance structure using a low-refractive-index material. It can be seen that the Q-factor decreases as Δw increases.

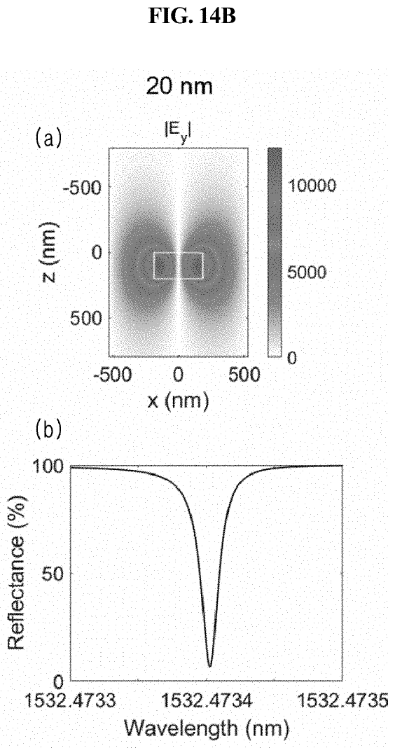

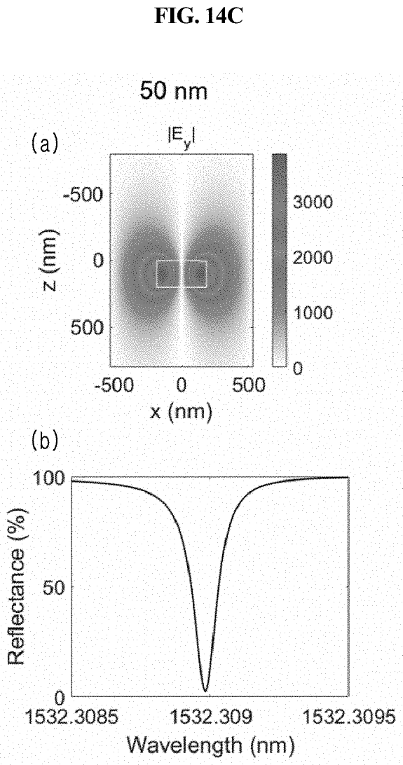

FIGS. 14A to 14C illustrate an excited mode and reflection spectrum in a resonance wavelength according to an increase in Δw of heterogeneous-material double-layer high-Q resonance structure according to the present disclosure. FIGS. 14A to 14C illustrate the excited mode distribution (a) and reflection spectrum (b) at the resonance wavelength as Δw of the heterogenous-material double-layer high-Q resonance structure having low-refractive-index (nₜ=1.48) upper layer diffraction grating having a thickness of several nm and a high-refractive-index (n_{b}=3.17) lower layer thickness approximately equal to the thickness of the HCG high-reflection mirror is changed to 10 nm/20 nm/50 nm. At Δw=10 nm, the Q-factor shows a very high value of 1.188×10¹⁰, and the maximum value of the excited |Ey| field strength also exceeds 2.5×10⁴. At w=20 nm, the Q-factor is 3.077×10⁹. At w=50 nm, the Q-factor is 4.703×10⁸.

As w increases, the FWHM of the reflection spectrum may be widened and the Q-factor may be lowered accordingly. The heterogeneous-material double-layer high-Q resonance structure with w=50 nm is higher than the single-material double-layer high-Q resonance structure in terms of Q-factor. In addition, similar to the single-material double-layer high-Q resonance structure, in the heterogeneous-material double-layer high-Q resonance structure, as w increases, the Q-factor decreases and the excited |Ey| field strength also gradually decreases. However, the shape of the excited mode is almost similar. Therefore, the Q-factor may be passively adjusted by adjusting w of the low-refractive-index layer. In addition, the desired Q-factor may be passively adjusted through additional thickness control. Regarding the resonance wavelength selection, in the case of a single-material double-layer high-Q resonance structure or a heterogeneous-material double-layer high-Q resonance structure, design to have a high Q-factor while changing the design parameters within the high reflection band of the HCG structure is possible.

The heterogeneous-material double-layer high-Q resonance structure may be formed through reactive ion etcher (RIE) after first patterning the HCG structure of the lower layer through an e-beam or deep ultraviolet (DUV) process. After that, the low-refractive-index layer having a thickness of several nm may be precisely deposited using an atomic layer deposition (ALD) method. Since a high Q-factor may be obtained even when Δw1≠Δw2, when a mask pattern covering a desired region is formed through e-beam lithography and a low-refractive-index material in an unwanted region is removed through dry or wet etching, a heterogeneous-material double-layer high-Q resonance structure may be formed.

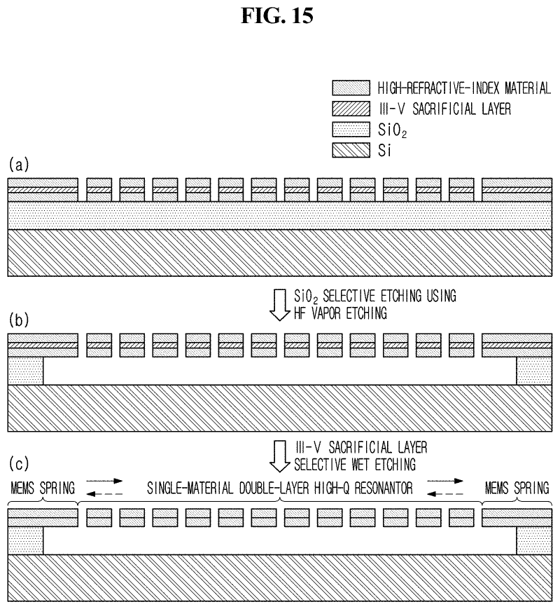

FIG. 15 illustrates a method of fabricating and operating a single-material double-layer high-Q resonance structure with a variable Q-factor according to the present disclosure. That is, FIG. 15 illustrates a structure fabrication method capable of actively adjusting the Q-factor of a single-material double-layer high-Q resonance structure. A substrate on which a high-refractive-index material including a sacrificial layer is grown is wafer-bonded to a SiO₂/Si substrate. After that, the III-V substrate is removed. After the substrate is removed, a diffraction grating illustrated in (a) of FIG. 15 is formed in the region through an RIE process after an e-beam lithography or DUV lithography process for forming diffraction grating. Next, as shown in (b) of FIG. 15, the SiO₂ layer is selectively removed using HF vapor etching, and the upper and lower portions of the diffraction grating structure are filled with an air layer. Next, as shown in FIG. 15c, the III-V sacrificial layer is removed through selective wet etching. After that, the upper and lower layers are separated, and the MEMS spring is moved from side to side, allowing one layer to move from side to side to deviate from the center of the unit grating.

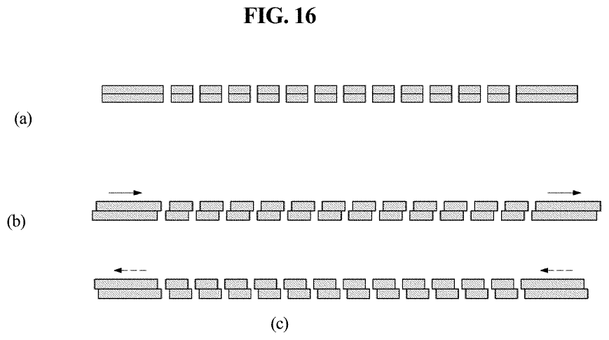

FIG. 16 illustrates an operation mode of a single-material double-layer resonance structure with a variable Q-factor according to the present disclosure. Specifically, (a) of FIG. 16 illustrates an HCG high-reflection mirror. When the upper and lower layers are aligned, they operate as HCG high-reflection mirrors. (b) and (c) of FIG. 16 illustrate a high-Q resonance structure capable of adjusting the Q-factor based on a MEMS spring that may move finely from side to side. When moving one layer from side to side through the MEMS spring, an object operates as a single-material double-layer resonance structure, and the Q-factor may be changed according to the movement distance.

Hereinafter, the effects of the present disclosure will be described. In the case of using BIC to find design parameters for designing a high-Q resonance structure, it takes a long time or the background reflectivity around the resonance wavelength is low. Therefore, it is difficult to satisfy a critical absorption condition. In addition, there is a disadvantage that it is difficult to systematically adjust the Q-factor. The HCG-based high-Q resonance structure disclosed in the present disclosure has very high background reflectivity because it is designed to inherit the HCG high-reflection mirror characteristics. In addition, in the HCG-based high-Q resonance structure disclosed in the present disclosure, it is easy to change the Q-factor passively or actively, so that not only the laser but also the photodetector can easily adjust the structure to achieve critical absorption. In addition, the HCG-based high-Q resonance structure disclosed in the present disclosure may respond sensitively to small changes. In addition, the HCG-based high-Q resonance structure disclosed in the present disclosure may be used in a light refractive-index sensor or various optical/optoelectronic devices due to the characteristics of the high-Q resonator. In addition, in the HCG-based high-Q resonance structure disclosed in the present disclosure, the Q-factor may be actively adjusted by introducing a MEMS spring structure to the single-material double-layer HCG resonator, or the Q-factor may be adjusted by using a low-refractive-index layer in a heterogeneous-material double-layer HCG structure and adjusting the width of the layer. In particular, a heterogeneous-material double-layer high-Q resonance structure using a low-refractive-index material shows a high Q-factor even under a condition in which the ow width for breaking symmetry is considerably wide.

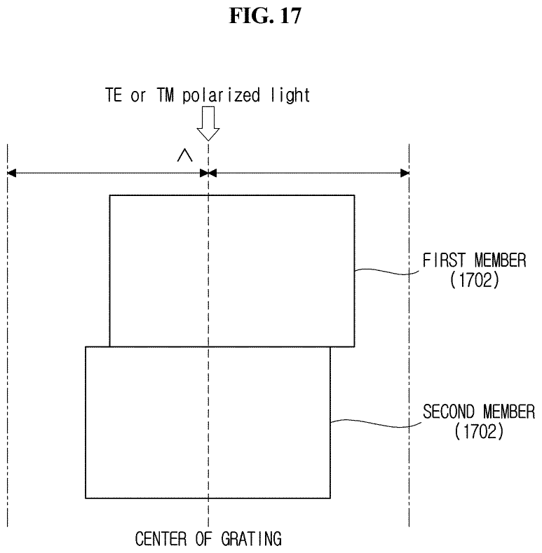

FIG. 17 illustrates an example of a high-Q resonance structure according to the present disclosure. Referring to FIG. 17, for example, an optical resonator may operate based on a single-material double-layer HCG resonance structure. An optical resonator based on a single-material double-layer HCG resonance structure includes a first member and a second member. Each of the first member and the second member has a high contrast grating (HCG) structure, and the refractive index of the first member and the refractive index of the second member are the same. As the sum of the first member HCG and the second member HCG, the optical resonator may perform an HCG high-reflection mirror operation, and may operate as a high-Q resonator.

In the optical resonator based on the single-material double-layer HCG resonance structure, the width of the first member and the width of the second member may be the same. A distance from the center of the second member to the center of the grating may be 0. An area of the first member and an area of the second member may be different. The area of the first member and the area of the second member may be the same. A distance from the center of the first member to the center of the grating may be different from a distance from the center of the second member to the center of the grating.

As another embodiment, the optical resonator may operate based on a heterogeneous-material double-layer high-Q resonance structure. The resonator based on a heterogeneous-material double-layer high-Q resonance structure includes a first member and a second member. Each of the first member and the second member has a grating structure, the second member has a high contrast grating (HCG) structure, and the refractive index of the first member and the refractive index of the second member are different. In the optical resonator based on the heterogeneous-material double-layer high-Q resonance structure, the second member HCG may operate as a high-reflection mirror. In the optical resonator based on the heterogeneous-material double-layer high-Q resonance structure, the first member may have a low contrast grating (LCG) structure. The optical resonator based on a heterogeneous-material double-layer high-Q resonance structure may operate as a high-Q resonator through the combination of the first member and the second member.

In the optical resonator based on the heterogeneous-material double-layer high-Q resonance structure, the refractive index of the second member may be higher than 3. A thickness of the second member may be greater than that of the first member. A distance from the center of the second member to the center of the grating may be 0, and the refractive index of the first member may be lower than that of the second member. A distance from the center of the first member to the center of the grating may be different from a distance from the center of the second member to the center of the grating. A width of the first member may be smaller than that of the second member. The refractive index of the first member may be lower than 2. An area of the first member and an area of the second member may be different. A thickness of the first member may be smaller than that of the second member. The first member may include SiO₂ or TiO₂. The second member may include silicon, InP, InGaAs, and Ge.

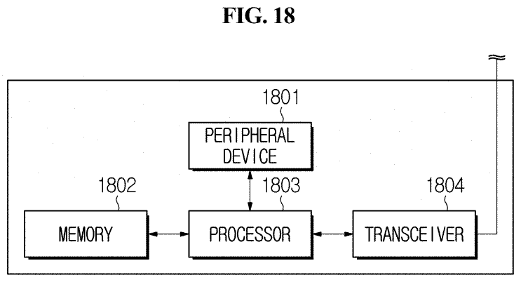

FIG. 18 illustrates an example of a configuration of a device according to the present disclosure. Referring to FIG. 18, the device may include a memory 1802, a processor 1803, a transceiver 1804, and a peripheral device 1801. In addition, as an example, the device may further include other components, and is not limited to the above-described embodiment. In this case, as an example, the device may be an optical resonator device. More specifically, the device of FIG. 18 may be exemplary hardware/software for optical resonance. In this case, as an example, the memory 1802 may be a non-removable memory or a removable memory. As an example, the peripheral device 1801 may include a laser irradiating TE (transverse electric) or TM (transverse magnetic) polarized light. Also, as an example, the peripheral device may include a first member and a second member. Here, the first member and the second member may include the low-refractive-index material or the high-refractive-index material described above with reference to FIGS. 1A to 17. Also, as an example, the peripheral device 1801 may include a display, a GPS, or other peripheral devices, and is not limited to the above-described embodiment. Also, as an example, the above-described device may include a communication circuit such as the transceiver 1804, and may communicate with an external device based thereon. Also, as an example, the processor may adjust the distance between the center of the first member and the center grating. In addition, the processor may adjust the distance between the center of the first member and the center grating. Also, as an example, the processor 1803 may include at least one of a general-purpose processor, a digital signal processor (DSP), a DSP core, a controller, a microcontroller, application specific integrated circuits (ASICs), field programmable gate array (FPGA) circuits, other types of integrated circuits (ICs) and one or more microprocessors associated with a state machine. That is, it may be a hardware/software configuration that performs control for controlling the above-described device. At this time, the processor 1803 may execute computer-executable instructions stored in the memory 1802 to perform various essential functions of the node. The processor 1803 may control at least one of signal coding, data processing, power control, input/output processing, or communication operations. Also, the processor 1803 may control a physical layer, a MAC layer, and an application layer. Also, as an example, the processor 1803 may perform authentication and security procedures at an access layer and/or an application layer, and the like, and is not limited to the above-described embodiment.

In addition, as an example, the processor 1803 may communicate with other devices through the transceiver 1804. For example, the transceiver 1804 may transmit/receive a PSNR value and an SSIM value calculated by the processor 1803. In addition, the transceiver 1804 may transmit a 3D spatial image or a flattened spatial image stored in the memory 1802 to the outside. In addition, the processor 1803 may control a node to communicate with other nodes through a network by executing computer-executable instructions. That is, communication performed in the present disclosure may be controlled. For example, the transceiver 1804 may transmit an RF signal through an antenna, and may transmit the signal based on various communication networks. Also, as an example, MIMO technology, beamforming, etc. may be applied as the antenna technology, and is not limited to the above-described embodiment. In addition, the signal transmitted/received through the transceiver 1804 may be modulated and demodulated and controlled by the processor 1803, but is not limited to the above-described embodiment.

The various embodiments of the present disclosure are not a list of all possible combinations and are intended to describe representative aspects of the present disclosure, and the matters described in the various embodiments may be applied independently or in combination of two or more.

In addition, various embodiments of the present disclosure may be implemented in hardware, firmware, software, or a combination thereof. In the case of implementing the present invention by hardware, the present disclosure can be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the disclosure includes software or machine-executable commands (e.g., an operating system, an application, firmware, a program, etc.) for enabling operations according to the methods of various embodiments to be executed on an apparatus or a computer, and a non-transitory computer-readable medium having such software or commands stored thereon and executable on the apparatus or the computer.

The present disclosure described above may be variously substituted, modified and changed by those of ordinary skill in the art, to which the present disclosure pertains, within the scope that does not depart from the technical spirit of the present disclosure, and thus the scope of the present disclosure is not limited by the above-described embodiments and the accompanying drawings.

What is claimed is:

1. An optical resonator comprising:
a first member; and
a second member,
wherein each of the first member and the second member has a high contrast grating (HCG) structure, and
wherein a refractive index of the first member and a refractive index of the second member are the same.

2. The optical resonator of claim 1, wherein a width of the first member and a width of the second member are the same.

3. The optical resonator of claim 1, wherein a distance from the center of the second member to the center of a grating is 0.

4. The optical resonator of claim 1, wherein an area of the first member and an area of the second member are different.

5. The optical resonator of claim 1, wherein an area of the first member and an area of the second member are the same.

6. The optical resonator of claim 1, wherein a distance from the center of the first member to the center of a grating and a distance from the center of the second member to the center of the grating are different.

7. The optical resonator of claim 1, wherein a width of the first member and a width of the second member are different.

8. An optical resonator comprising:
a first member; and
a second member,
wherein each of the first member and the second member has a grating structure, and
wherein the second member has a high contrast grating (HCG) structure and a refractive index of the first member and a refractive index of the second member are different.

9. The optical resonator of claim 8, wherein the refractive index of the second member is higher than 3.

10. The optical resonator of claim 8, wherein a thickness of the second member is greater than that of the first member.

11. The optical resonator of claim 8, wherein a distance from the center of the second member to the center of a grating is 0, and the refractive index of the first member is lower than that of the second member.

12. The optical resonator of claim 8, wherein a distance from the center of the first member to the center of a grating and a distance from the center of the second member to the center of the grating are different.

13. The optical resonator of claim 8, wherein a width of the first member is smaller than that of the second member.

14. The optical resonator of claim 8, wherein the refractive index of the first member is lower than 2.

15. The optical resonator of claim 8, wherein an area of the first member and an area of the second member are different.

16. The optical resonator of claim 8, wherein a thickness of the first member is less than that of the second member.

17. The optical resonator of claim 14, wherein the first member includes SiO₂ or TiO₂.

18. The optical resonator of claim 9, wherein the second member includes silicon, InP, InGaAs and Ge.
